(19) United States
(12) Patent Application Publication
(10) Pub. No.: US 2023/0119683 A1
(43) Pub. Date: Apr. 20, 2023

(54) A RARE-EARTH METAL OXYHYDRIDE BASED SUPERCONDUCTIVE THIN FILM AND ITS MANUFACTURING METHOD

(71) Applicant: Institutt for Energiteknikk, Kjeller (NO)

(72) Inventors: Elbruz Murat BABA, Oslo (NO); Smagul KARAZHANOV, Oslo (NO)

(73) Assignee: Institutt for Energiteknikk, Kjeller (NO)

(21) Appl. No.: 17/914,879

(22) PCT Filed: Apr. 15, 2021
(86) PCT No.: PCT/EP2021/059724

§ 371 Date: Sep. 27, 2022

(30) Foreign Application Priority Data
Apr. 15, 2020 (NO) 20200459

(51) Int. Cl. C23C 14/06; C23C 14/58; C03C 17/22; C23C 14/35; C23C 14/00

(52) U.S. Cl. CPC C23C 14/06; C23C 14/5853; C03C 17/22; C23C 14/35; C23C 14/0036

(57) ABSTRACT

The present invention relates to a superconductive rare-earth metal oxyhydride material and a method for producing the material. The method comprising the steps of: —first the formation on a substrate of a layer of an oxygen free rare-earth metal hydride with a predetermined thickness using a physical vapor deposition process; and —second exposing the rare-earth metal hydride layer to oxidative agent for oxidation where the oxygen reacts with the rare-earth metal hydride that results with obtaining rare-earth metal oxyhydride, the oxidation being below a predetermined limit defined by a measured transparency being less than 10%.

The present invention is in the field of production of superconductor thin films.

Oxyhydrides have been an emerging field the recent years and been the object of research in order to understand the material properties under varying conditions. One motivation being potentially low material production costs for a wide variety of applications. As an example, the photochromic properties as well as different fabrication methods and compositions have been discussed in WO2018/024394 and WO2017/125573A1 showing promising results in the field of photochromic materials.

It has been shown recently (Cornelius2019, Oxyhydride Nature of Rare-Earth-Based Photochromic Thin Films, doi:10.1021/acs.jpclett.9b00088 and Nafezarefi2017, Photochromism of rare-earth metal-oxy-hydrides, doi:10.1063/1.4995081) that production methods that have been described in the mentioned patent applications are valid for all rare-earth metals where yttrium can be named as an archetype.

Further, (Pavlo Mikheenko, Elbruz Murat Baba, and Smagul Karazhanov. “Electrical and magnetic behavior of GdOH thin films: a search for hydrogen anion superconductivity.” In Microstructure and Properties of Micro-and Nanoscale Materials, Films, and Coatings (NAP 2019), pp. 1-7. Springer, Singapore, 2020.) report anomalous resistive and magnetic behavior of GdOH thin films.

Superconductivity is a set of physical properties including disappearing electrical resistance and expulsion of magnetic flux fields. Unlike metals where resistance reduce gradually following a temperature reduction, superconductors have a transition temperature (Tc) below which electrical resistivity reaches zero. The rate (slope) of resistivity decrease can vary depending on various factors, e.g. as reported in Yu2019 (Yu2019, High-temperature superconductivity in monolayer Bi₂Sr₂CaCu₂O_{8+δ} doi: 10.1038/s41586-019-1718-x) where different resistivity drop rates, and even resistivity increases, is strongly dependent on the doping level of the material.

The present invention relates to a fabrication method and product providing superconductivity. This is achieved as presented in the accompanying claims.

The fabrication method according to the invention is described as follows: an initial reactive sputter deposition, in a hydrogen/argon mix atmosphere, of a metal hydride thin film based on a rare-earth (RE) metal, more specifically gadolinium, followed by a subsequent oxidation by exposing to air or by an oxidation agent. The concentration of oxygen used to treat the metal hydride may vary but should be sufficient for obtaining the desired oxygen/metal ratio but should not exceed the ratio where the resulting material becomes a transparent photochromic material as described in WO2018/024394 or in literature where the chemical formula range for oxygen content given for transparent photochromic REH_{2-δ}O_{δ} (Moldarev2018, Yttrium oxyhydrides for photochromic applications: Correlating composition and optical response, doi:10.1103/PhysRevMaterials.2.115203) is 0.40<δ. It was also reported that well established photochromic, transparent rare-earth metal oxyhydride films are highly resistive (Mongstad2011, A new thin film photochromic material: Oxygen-containing yttrium hydride doi:10.1016/j.solmat.2011.08.018) and demonstrates stark distinction from the material presented according to the present invention. The resulting material according to this invention is a rare-earth metal oxyhydride that possess superconductivity, is opaque and has a different structure compared to the initially deposited rare-earth metal hydride prior to the oxidation.

The present invention thus concerns a method of producing a rare-earth metal oxyhydride-based (REMOH) superconductive film to be described based on the example of gadolinium oxyhydride. The substrate comprises a transparent or an opaque material, more specifically glass, strontium titanate or single crystalline intrinsic silicon wafer, and at least one layer deposited on top of it including a superconductive layer comprising of REMOH. Similar to the patent application WO2018/024394 A1 the method of preparation of the REMOH-based superconductive layer comprises two steps: a layer of rare-earth metal hydride on a substrate with a predetermined thickness using a physical vapor deposition process; and -second oxidation of the films. The resulting film is also a highly absorptive photoactive material, and after oxidation films should be kept clear from excitation from light sources.

The invention will be described more in detail with reference to the accompanying drawings, illustrating the reason of the improvement to the device described above:

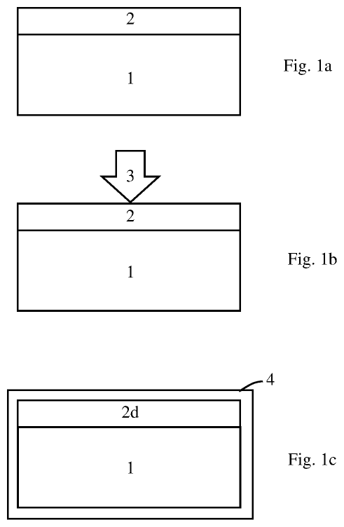

FIG. 1 Illustrates the production method according to the invention.

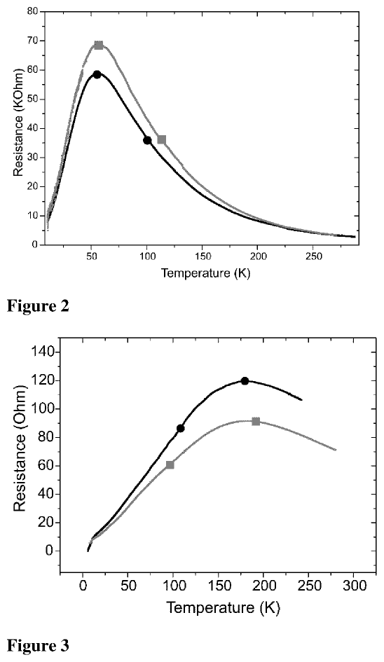

FIG. 2 Demonstrates the temperature dependent resistance measurements for gadolinium oxyhydride on glass substrates.

FIG. 3 Demonstrates the temperature dependent resistance measurements for gadolinium oxyhydride on strontium titanate substrates.

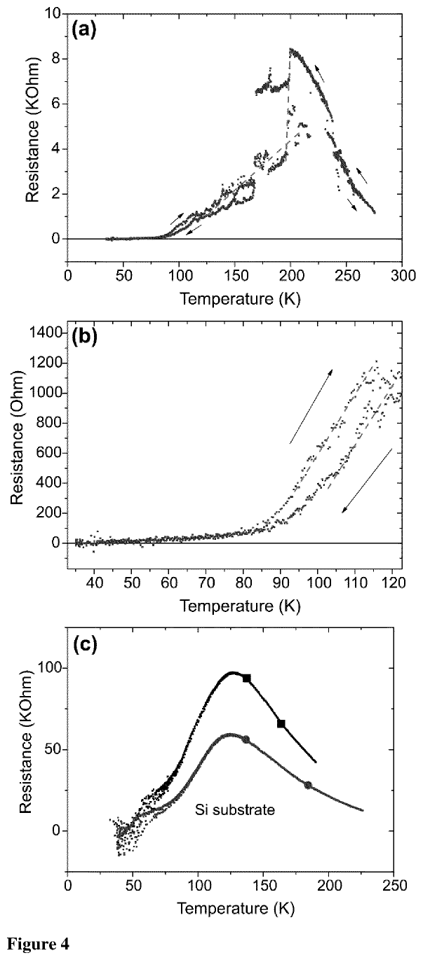

FIG. 4 Demonstrates temperature dependent resistance measurements for gadolinium oxyhydride films using single-crystalline silicon substrates.

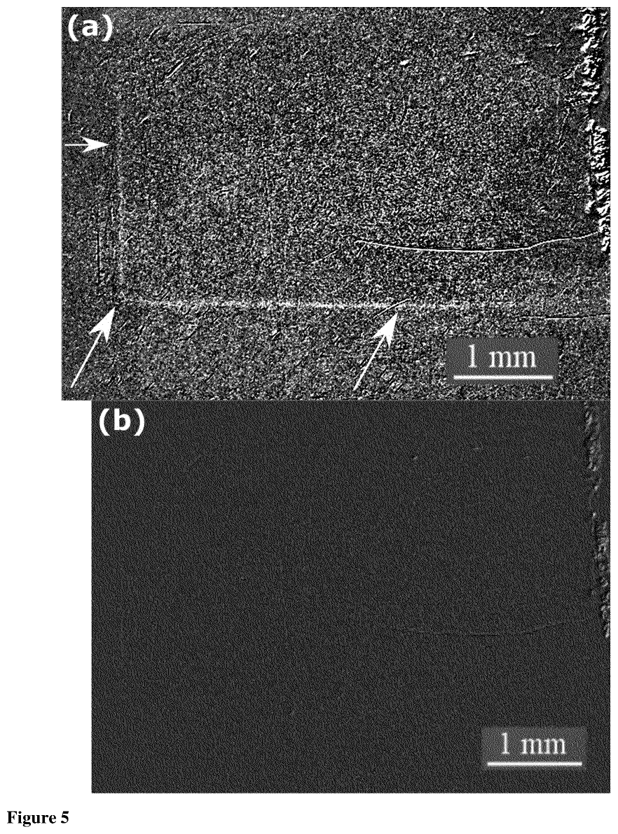

FIG. 5 Shows an image produced using the magneto-optical imaging (MOI) technique at (a) 5.9 K where the trapped magnetic field is visible at the border of the film, indicating that the gadolinium oxyhydride material deposited on strontium titanate substrate have superconducting properties. Image (b) shows the same film at a higher temperature of 16.0 K where the magnetic field is no longer trapped.

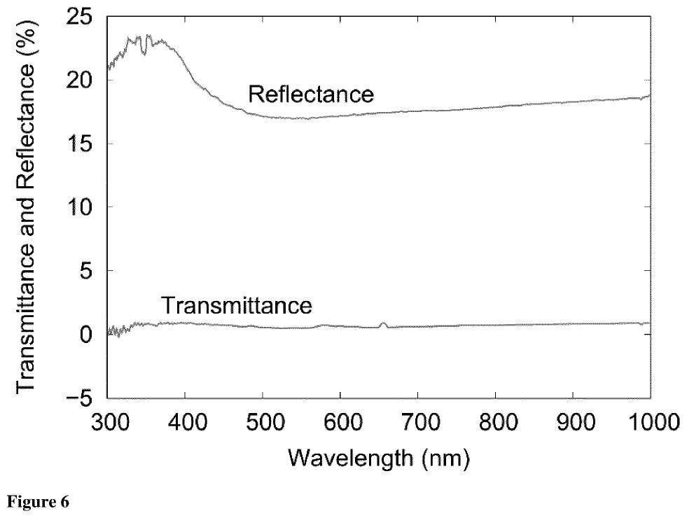

FIG. 6 Demonstrates transmittance and reflectance of the gadolinium oxyhydride film, deposited on glass substrate. The film has been used for temperature dependent resistivity measurements.

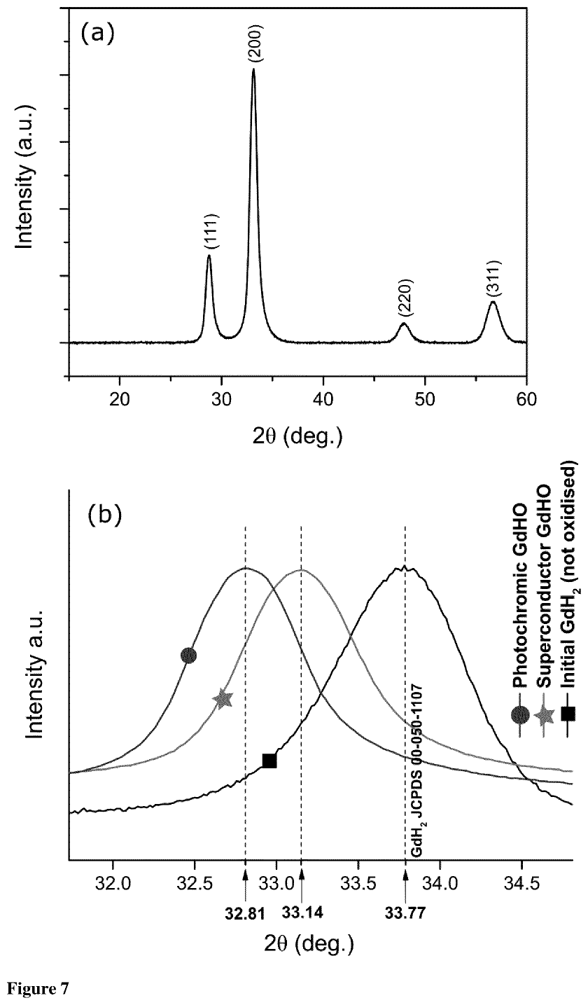

FIG. 7 Demonstrates XRD diffractogram for gadolinium oxyhydride films deposited on glass substrate. (a) The film has been used for temperature dependent resistivity measurements. (b) Diffraction peak difference between initial sputtered material (not oxidized), superconducting GdHO and photochromic GdHO based on oxidation levels.

FIG. 1a-c illustrates the production method according to the invention where the process with the deposition of an essentially oxygen-free rare-earth metal hydride 2 onto a substrate 1 (e.g., glass, strontium titanate, carbon, silicon wafer or a polymer-based substrate) as in FIG. 1a. The preferred fabrication method according to the invention relates to the production method described as follows: an initial reactive sputter deposition, using pulsed DC magnetron sputtering with pre-deposition base pressure between 5×10⁻⁸ and 9×10⁻⁶ mbar, in a hydrogen/argon mix atmosphere where H₂/Ar ratio between 0.15 and 0.25 (more specifically 0.21), deposition chamber pressure between 6×10⁻³ and 1.5×10⁻² mbar (more specifically 1×10⁻² mbar) of a metal hydride thin film based on a rare-earth metal, more specifically gadolinium. By the deposition procedure one can obtain oxygen-free rare-earth metal hydride layer 2 containing at least one dominating phase of rare-earth metal di-hydride, specifically gadolinium di-hydride, GdH₂₋ₓ where x between 0≤x≤0.5.

The deposition is followed by a subsequent oxidation by exposing the hydride film into air. The water content in air is equivalent to a room that has relative humidity (RH) between 0<RH≤10% at 25° C. The sample can also be oxidized by oxidation agents, e.g, moisture, water, water vapor, hydrogen peroxide, hydrogen peroxide solution, ozone, or oxygen, up to same oxidation rate of a sample in air with water content per volume or moisture density is equivalent to a room that has relative humidity (RH) in the range of 0<RH≤10% at 25° C. The oxygen/metal ratio but should not exceed the level where the resulting material would become a transparent photochromic material described in WO2018/024394 and in literature where the chemical formula range for oxygen content given for transparent photochromic REH_{2-δ}O_{δ} (Moldarev2018, Yttrium oxyhydrides for photochromic applications: Correlating composition and optical response, doi:10.1103/PhysRevMaterials.2.115203) is 0.40<δ. Oxygen content in the present invention is less than the mentioned patent application and literature references and cannot be described as photochromic rare-earth metal oxyhydride. The resulting material is the rare-earth metal oxyhydride that possess superconductivity and that is opaque with a new structure compared to the initially deposited rare-earth metal hydride. The metal hydride 2 may comprise a metal from the groups of rare-earth elements, but according to the preferred embodiment of the invention the metal is gadolinium, forming gadolinium hydride.

In the case where the metal hydride 2 is gadolinium hydride, x-ray diffraction has been used to show that crystal structure of this metal hydride is the same as that of gadolinium-dihydride (GdH₂₋ₓ). The crystal structure is face centered cubic with the lattice parameters matching the one reported (Ellner1998 Journal of Alloys and Compounds 279 (1998) 179-183) and Joint Committee on Powder Diffraction Standards (JCPDS) card number 00-050-1107, GdH₂, i.e. 0.530 nm. Although gadolinium hydride is referred to in the present application, other materials having the same structure will exhibit similar properties, such as yttrium hydride, as is shown in the literature (Cornelius2019, Oxyhydride Nature of Rare-Earth-Based Photochromic Thin Films, doi:10.1021/acs.jpclett.9b00088, Pishtshev2019, Conceptual Design of Yttrium Oxyhydrides: Phase Diagram, Structure, and Properties, doi:10.1021/acs.cgd.8b01596), may be used.

The final product is obtained by oxidizing with an oxidation agent, e.g., using air and/or any of the following: oxygen, moisture, humidity, water, water vapor, hydrogen peroxide, hydrogen peroxide solution, ozone. As will be discussed below, the oxygen content should be in the range where the optical appearance is different, i.e., material is opaque, from what was discussed in WO2018/024394 which describes the preparation of photochromic yttrium oxyhydride. Thus, the production methods differ in the amount of supplied oxygen. Whereas a large supply of oxygen will provide a photochromic material as in WO2018/024394, the present invention uses low amounts of oxygen and has low or preferably no photochromic response.

For the particular case where the as-deposited metal hydride is gadolinium hydride, the resulting material after oxidation is multiphase and consists of at least one dominating phase possessing the fcc crystal structure of F4̅3m or Fm3̅m symmetry. This phase is comprised of at least gadolinium, hydrogen and oxygen, where gadolinium mainly occupies the main lattice sites while oxygen occupies the tetrahedral lattice sites with occupancy of less than 40%.

The porosity, microstructure (the arrangement and size of grains, agglomerates of grains, and micro cracks) of and hydrogen concentration in the as-deposited metal hydride as well as the temperature of environment and oxidation agents are highly important in determining the subsequent degree of post-deposition oxidation of the metal hydride film. In a porous material defined as a material that is not continuous, but which contains pores, voids, columns and cavities—the diffusion of oxygen will take place mainly through these pores, interfaces between columns and cavities besides from the surface. Reaction with humidity (or equivalent water content described above) will further enhance porosity of the films.

The substrate is opaque or transparent and single crystalline, poly crystalline or amorphous, where the aim of the superconductive layer is to provide conductivity with no resistance below certain temperature.

In FIG. 1b the metal hydride is oxidized 3 by an oxidation agent (e.g., air and/or oxygen, moisture, humidity, water, water vapor, hydrogen peroxide, hydrogen peroxide solution, ozone, etc.). Humidity in this case referring to any one of water vapor, liquid water in air or liquid water, as it is the chemical response with the water molecules that initiates the reaction.

Superconductivity of the material arises by the substitution of oxygen for hydrogen (Moldarev2018, Yttrium oxyhydrides for photochromic applications: Correlating composition and optical response, doi: 10.1103/PhysRevMaterials.2.115203) during oxidation following the deposition of the material. Controlling the oxidation level is important to preserve the chemical pressure that induced by oxygen incorporation inside the lattice as the lattice expands (Maehlen2013, Lattice contraction in photochromic yttrium hydride, doi: 10.1016/j.jallcom.2013.03.151). We refer to the chemical pressure as a virtual pressure induced by isovalent substitution that has been used to tune properties in solids including superconductive properties (Yamashita2018, Chemical Pressure-Induced Anion Order-Disorder Transition in LnHO Enabled by Hydride Size Flexibility, doi:10.1021/jacs.8b06187; Sanchez-Benitez2010 Enhancement of the Curie Temperature along the Perovskite Series RCu₃Mn₄O₁₂ Driven by Chemical Pressure of R³⁺ Cations (R=Rare Earths), doi:10.1021/ic100699u; Marezio2000, Chemical pressure for optimizing Tc in a given superconducting system, doi:10.1016/S0921-4534(00)00090-3). It has been shown that chemical pressure can induce superconductivity (Jinno2016, Bulk Superconductivity Induced by In-Plane Chemical Pressure Effect in Eu_{0.5}La_{0.5}FBiS₂₋ₓSeₓ, 10.7566/JPSJ.85.124708) as well as improve (Jha2020, Improvement of superconducting properties by chemical pressure effect in Eu-doped La₂₋ₓEuₓO₂Bi₃Ag_{0.6}Sn_{0.4}S₆, doi:10.1016/j.physc.2020.1353731) whether by reducing the lattice parameters or enhancing the packing density (Mizuguchi2015, In-plane chemical pressure essential for superconductivity in BiCh2-based (Ch: S, Se) layered structure, doi: 10.1038/srep14968). It should also be mentioned that compressive stress, which can be considered as a substitute for an external pressure that is one of the prominent requirements for high temperature superconductors, has been reported as a result of oxidation of the initial deposited gadolinium hydride (Hans2020, Photochromic Mechanism and Dual-Phase Formation in Oxygen-Containing Rare-Earth Hydride Thin Films, doi:10.1002/adom.202000822).

Any effect that would jeopardize the bond structure after oxidation should, therefore, be avoided. It is known from experiments (Baba2019, Light-induced breathing in photochromic yttrium oxyhydrides, doi: 10.1103/PhysRevMaterials.4.025201) that weakening of oxygen bonds in rare-earth oxyhydrides can be induced by light exposure. Even though the appearance of the superconductor layer is black (contrary to the photochromic oxyhydrides), the material itself still preserves its rare-earth oxyhydride photoactive nature and highly absorptive. For this reason, controlling oxygen levels in superconductive material through protection from environment is critical.

In FIG. 1c the substrate 1 and the resulting oxyhydride is enclosed in a container 4 or similarly encapsulated for keeping the superconductive material clear from environmental interactions and further oxidation as well as keeping the oxygen levels stable inside the material.

In some cases, the container 4 should also allow little or no light transmission as the oxyhydride may be sensitive to light as described above. Experiments have shown that light exposure to the material will result with loss in superconductivity even when the photochromic effect is not visible. This can be called as superconductivity that can be controlled by illumination with UV light.

FIGS. 2-7 shows measurements made with produced samples of the oxyhydride according to the invention.

In FIG. 2 the electrical conductivity of two samples of gadolinium oxyhydride deposited on a glass substrate is shown that resistance reduction following temperature decrease starting around 55 K, from 55-70 kiloohm to less than 10 kiloohm, multiple of times, measured by temperature dependent resistance measurement.

In FIG. 3 two samples of gadolinium oxyhydride deposited on a single crystalline strontium titanate substrate demonstrates resistance reduction following temperature decrease starting around 160 K, from 79-120 kiloohm then approaching to 0 ohm (magenta-square) and reaching to 0 ohm (black-circular), measured by temperature dependent resistance measurement.

In FIG. 4 gadolinium oxyhydride deposited on a single crystalline silicon wafer substrate demonstrates where results in graph (a,b) and (c) are from two different samples that demonstrates the behavior reproducibility; (a) resistance reduction following temperature decrease from 200 K and reaching 0 ohm below the temperature of 50 K. In this state, the film exhibits behavior characteristic to superconductivity as having no resistance after certain temperature where resistance of the material also follows the same path while temperature increased, shown by arrows (a and b). (c) Second sample shows the resistance reduction depending on temperature starting from around 125 K and approaching 0 ohm around 50 K shows superconductive behavior.

In FIG. 5, a non-destructive method benefiting from Meissner Effect to investigate superconductor films, magneto-optical imaging (MOI) technique was employed to demonstrate the further proof of superconductor behavior of GdHO. MOI gives the direct information about the distribution of magnetic flux in the sample and referring to this article (Mikheenko2012, Magneto-optical Imaging of Columnar YBCO Films, doi:10.1016/j.phpro.2012.06.179) we confirm that this image shows a trapped magnetic field at the border of the film. MOI image at 5.9 K (a) highlights the outer border (arrows are pointing the border) of superconductive gadolinium oxyhydride material deposited on strontium titanate as a result of the expulsion of magnetic field effect known as Meissner Effect. The presence of magnetic field expulsion is clearer when compared to (b) the reference image taken at 16 K shows no such border or indication of magnetic field expulsion, proving further the former image in (a) is not an artefact.

In FIG. 6 transmittance and reflectance values were shown between 300-1000 nm. Superconductive gadolinium oxyhydride shows opaque behavior where more than 15% light is reflected.

In FIG. 7 (a) XRD diffractogram for superconductive gadolinium oxyhydride with indicated reflection planes shows characteristic peaks of oxyhydrides. Material possesses at least one phase of CaF₂ type fcc crystal structure with F4̅3m or Fm3̅m symmetry where lattice parameters can be between 0.53 and 0.55 nm, preferably 0.54 nm. (b) Diffraction peak location difference based on oxidation shown between initially deposited gadolinium hydride (not oxidized, square), photochromic gadolinium oxyhydride (circle) and superconductive gadolinium oxyhydride (star). As can be seen the superconductive material has a diffraction peak at about 33.14 degrees.

To summarize the present invention relates to a method for producing a superconductive oxyhydride material as well as the resulting superconductive component where the method comprises the steps of formation on a substrate of a layer of an essentially oxygen free metal hydride with a predetermined thickness preferably within the range of 20-1500 nm, preferably around 500 nm using a physical vapor deposition process. The substrate will preferably be a transparent or opaque substrate, e.g., a glass, strontium titanate or single crystalline silicon wafer. Following this the metal hydride layer is exposed to an oxidative agent for oxidation where the oxygen reacts with the metal hydride. The oxidation may be provided in several way, both from air, humidity or other means resulting in a transfer of oxygen into the material. The oxidation is below a predetermined limit, preferably below 40%: where percentage express the oxygen occupancy level in the lattice that yttrium occupies main sites and oxygen occupies tetrahedral sites. The predetermined limit could be 40%, 30%, 20% or 10%, or ranges such as 1% to 40%, 10% to 40%, 10% to 30% or 25% to 40% where the resulting material chemical formula should be REH_{2-δ}O_{δ} δ<0.40.

The rare earth metal hydride is preferably constituted by a gadolinium hydride.

Following the oxidation step the method preferably includes a step of enclosing the material with an encapsulant with low oxygen transmission, the encapsulant e.g., being constituted by a metal, metal oxide and/or suitable polymer based on known properties related to oxygen transmission. The metal hydride may have a porosity being above zero, i.e., it contains hollow pores, columns, voids and/or cavities to improve the absorption of oxygen in the rare earth oxyhydride. The porosity can be further enhanced by the process of oxidation of the hydride.

The metal hydride may be fabricated on a transparent or opaque substrate, e.g., on top of a glass, strontium titanate or silicon wafer.

The resulting superconductive component will thus be constituted by a, opaque, rare earth metal oxyhydride, wherein the oxidation level is below a predetermined limit, preferably below 40%: where percentage express the oxygen occupancy level in the lattice, where the component may be constituted by the metal oxyhydride being positioned on a first, transparent or opaque substrate and wherein the metal oxyhydride is enclosed by an encapsulant that blocks oxygen transmissivity.

According to one preferred aspect of the invention a superconductive component is provided comprising a transparent or opaque substrate and a layer constituted metal oxyhydride where the oxyhydride is made from a metal oxyhydride, preferably a gadolinium oxyhydride, which can be made using the method described above.

1. A method for producing a superconductive rare-earth metal oxyhydride material, the method comprising:
forming on a substrate a layer of an oxygen free rare-earth metal hydride with a predetermined thickness using a physical vapor deposition process; and
exposing the rare-earth metal hydride layer to oxidative agent where the oxygen reacts with the rare-earth metal hydride for obtaining an opaque rare-earth metal oxyhydride.

2. The method according to claim 1, wherein the rare earth metal hydride is a gadolinium hydride.

3. The method according to claim 1, the steps being followed by the step of enclosing the material with an encapsulant that blocks oxidation,

4. The method according to claim 3, wherein the encapsulant is constituted by at least one of a metal, metal oxide, and polymer.

5. The method according to claim 1, wherein the formation on a substrate of a layer of an oxygen free metal hydride is provided as follows: an initial reactive sputter deposition, using pulsed DC magnetron sputtering with pre-deposition base pressure is between 5.10⁻⁷ and 9.10⁻⁶ mbar, in a hydrogen/argon mix atmosphere, the H₂/Ar ratio being between 0.15 and 0.25 more specifically 0.21, deposition chamber pressure being between 6.10⁻³ and 15.10⁻³ mbar, more specifically 1.10⁻² mbar, of a hydride of a rare-earth metal, more specifically gadolinium, resulting in an oxygen-free rare-earth metal hydride layer containing at least one phase of rare-earth metal di-hydride, specifically gadolinium di-hydride, GdH₂.

6. The method according to claim 1, wherein the exposure of the metal hydride to oxygen is performed by exposing to air where the water content in air is equivalent to a room that has relative humidity (RH) between 0<RH≤10% at 25° C.

7. The method according to claim 1, wherein the exposure of the metal hydride to oxygen is performed by treating the sample by oxidation agents, from the group of moisture, humidity, water, water vapor, hydrogen peroxide, hydrogen peroxide solution, and ozone.

8. The method according to claim 1, wherein the metal hydride is fabricated on a transparent or opaque substrate.

9. A superconductive component comprising an opaque rare-earth metal oxyhydride, produced according to the method of claim 1, wherein the oxidation level is below a predetermined limit defined by REH_{2-δ}O_{δ} where δ≤0.40.

10. The superconductive component according to claim 9, wherein the rare-earth metal is Gadolinium.

11. The superconductive component according to claim 9, wherein the rare-earth metal hydride consists of at least one phase possessing the fcc crystal structure with F4̅3m or Fm3̅m symmetry, thus being comprised of at least gadolinium, hydrogen and oxygen, the gadolinium mainly occupying the main lattice sites while oxygen occupies the tetrahedral lattice sites with occupancy of less than 40%.

12. The superconductive component according to claim 9, wherein the rare-earth metal oxyhydride is positioned on a first, transparent or opaque substrate and wherein the metal oxyhydride is enclosed by an encapsulant that blocks oxidation.

13. Superconductive component according to claim 9, wherein the oxyhydride material has a porosity containing hollow pores, voids and/or cavities.

14. The method according to claim 8, wherein the transparent or opaque substrate is on top of a glass, strontium titanate, or silicon wafer.
